(19) United States
(12) Patent Application Publication
(10) Pub. No.: US 2019/0189656 A1
(43) Pub. Date: Jun. 20, 2019

(54) PIXEL UNIT HAVING PHOTODIODES WITH DIFFERENT PHOTOSENSITIVE AREAS, AN IMAGING APPARATUS INCLUDING THE SAME, AND AN IMAGING METHOD THEREOF

(71) Applicants: Yaowu Mo, Shanghai (CN); Chen Xu, Santa Clara, CA (US); Zexu Shao, Shanghai (CN); Weijian Ma, Shanghai (CN); Guanjing Ren, Shanghai (CN); Wenjie Shi, Shanghai (CN); Xiao Xie, Shanghai (CN)

(72) Inventors: Yaowu Mo, Shanghai (CN); Chen Xu, Santa Clara, CA (US); Zexu Shao, Shanghai (CN); Weijian Ma, Shanghai (CN); Guanjing Ren, Shanghai (CN); Wenjie Shi, Shanghai (CN); Xiao Xie, Shanghai (CN)

(73) Assignee: SmartSens Technology (US) Inc., Santa Clara, CA (US)

(21) Appl. No.: 16/223,110

(22) Filed: Dec. 17, 2018

(30) Foreign Application Priority Data
Dec. 19, 2017 (CN) 201711378352.0
Feb. 8, 2018 (CN) 201810130550.3

(51) Int. Cl. H01L 27/146; H04N 5/3745; H04N 5/355

(52) U.S. Cl. CPC H01L 27/14612; H04N 5/3559; H01L 27/14645; H04N 5/3745

(57) ABSTRACT

Disclosed are a pixel unit, an apparatus thereof, and a method thereof. The pixel unit comprises a first and a second transfer transistors with different photosensitive areas coupled to a floating diffusion and transfer the charges generated by a first and a second photodiodes in response to incident light during an exposure period and accumulated in the photodiode during said exposure period thereto; a capacitor with a first end coupled to a specified voltage; a gain control transistor coupled between the second end of the capacitor and the floating diffusion for imposing an isolation control therebetween; a reset transistor coupled to the second end of the capacitor and the gain control transistor for resetting the level of the coupling point therebetween via a reset control signal; and a source follower transistor coupled to the floating diffusion for amplifying and outputting the pixel signals.

### CROSS-REFERENCE TO RELATED U.S. APPLICATIONS

This application claims benefit of priority under the Paris Convention based on Chinese Application No. 201711378352.0 filed on Dec. 19, 2017 and Chinese Application No. 201810130550.3 filed on Feb. 8, 2018; and the entire disclosures of both applications are incorporated herein by reference.

### FIELD OF THE INVENTION

The present invention relates to the field of imaging, particularly relates to a pixel unit having photodiodes with different photosensitive areas, an imaging apparatus including the same, and an imaging method thereof. The present invention can find applications in a computer, a camera, a scanner, a machine vision, a vehicle navigator, a video phone, a surveillance system, an automatic focusing system, a star tracker system, a motion detection system, an image stabilization system and a data compression system, among others.

### BACKGROUND OF THE INVENTION

Demands for image qualities have been continually increasing. In particular, current imaging research and development have contributed many efforts to obtain a high-quality image without the aid of hardware with complex structure. For example, a high quality picture having a high resolution is required on a portable imaging apparatus such as a card like camera.

An imaging apparatus typically has an array of pixels. Each pixel in the pixel array comprises a photosensitive device, such as a photodiode, a light switch and the like. Each photosensitive device may have different capability for light receiving. These different capabilities are reflected to the imaging apparatus so that the imaging apparatus can have various light dynamic ranges, i.e. the light ranges that can be received by an imaging apparatus. When the light dynamic range of an imaging apparatus is less than the light intensity of an environment, the environmental scene cannot be completely reflected in the obtained image. There is always a need for a convenient way to address this problem in the art.

Advantageously, the present invention provides a solution that can meet this need, among others.

### SUMMARY OF THE INVENTION

One aspect of the present invention provides a pixel unit comprising (1) a first photodiode; (2) a first transfer transistor, which is coupled to a floating diffusion and transfers the charges generated by the first photodiode in response to incident light during an exposure period and accumulated in the photodiode during said exposure period to the floating diffusion; (3) a second photodiode; (4) a second transfer transistor, which is coupled to a floating diffusion and transfers the charges generated by the second photodiode in response to incident light during an exposure period and accumulated in the photodiode during said exposure period to the floating diffusion, wherein the photosensitive area of the second photodiode is different from the photosensitive area of the first photodiode, and wherein said two transfer transistors share the same floating diffusion; (5) a capacitor, the first end of which is coupled to a specified voltage; (6) a gain control transistor coupled between the second end of the capacitor and the floating diffusion for imposing an isolation control between the capacitor and the floating diffusion; (7) a reset transistor coupled to the second end of the capacitor and the gain control transistor for resetting the level of the coupling point between the second end of the capacitor and the gain control transistor via a reset control signal; and (8) a source-follower transistor coupled to the floating diffusion for amplifying and outputting the pixel signals.

Another aspect of the invention provides an imaging apparatus comprising a plurality of pixel unit arrays arranged in rows and columns. Each of the pixel unit comprises (1) a first photodiode; (2) a first transfer transistor, which is coupled to a floating diffusion and transfers the charges generated by the first photodiode in response to incident light during an exposure period and accumulated in the photodiode during said exposure period to the floating diffusion; (3) a second photodiode; (4) a second transfer transistor, which is coupled to a floating diffusion and transfers the charges generated by the second photodiode in response to incident light during an exposure period and accumulated in the photodiode during said exposure period to the floating diffusion, wherein the photosensitive area of the second photodiode is different from the photosensitive area of the first photodiode; (5) a capacitor, the first end of which is coupled to a specified voltage; (6) a gain control transistor coupled between the second end of the capacitor and the floating diffusion for imposing an isolation control between the capacitor and the floating diffusion; (7) a reset transistor coupled to the second end of the capacitor and the gain control transistor for resetting the level of the coupling point between the second end of the capacitor and the gain control transistor via a reset control signal; and (8) a source-follower transistor coupled to the floating diffusion for amplifying and outputting the pixel signals. The imaging apparatus further comprises a peripheral circuit for controlling the pixel array, and receiving and processing the image signals output by the pixel array output.

Still another aspect of the invention provides an imaging method in a pixel unit as described above. The method comprises the following steps: obtaining a first reset voltage of the floating diffusion in a first conversion gain mode; obtaining a second reset voltage of the floating diffusion in a second conversion gain mode; obtaining a second signal voltage of the floating diffusion in the second conversion gain mode; obtaining a first signal voltage of the floating diffusion in the first conversion gain mode; obtaining a first valid signal through a dual-correlation operation based on the first reset voltage and the first signal voltage; and obtaining a second valid signal through a dual-correlation operation based on the second reset voltage and the second signal voltage.

The above features and advantages and other features and advantages of the present invention are readily apparent from the following detailed description of the best modes for carrying out the invention when taken in connection with the accompanying drawings.

### BRIEF DESCRIPTION OF THE SEVERAL VIEWS OF THE DRAWINGS

The present invention is illustrated by way of example, and not by way of limitation, in the figures of the accompanying drawings and in which like reference numerals refer to similar elements. All the figures are schematic and generally only show parts which are necessary in order to elucidate the invention. For simplicity and clarity of illustration, elements shown in the figures and discussed below have not necessarily been drawn to scale. Well-known structures and devices are shown in simplified form in order to avoid unnecessarily obscuring the present invention. Other parts may be omitted or merely suggested.

FIG. 1 is a schematic diagram of the structure of an imaging apparatus;

FIG. 2 is a schematic diagram of a pixel unit according to one embodiment of the present invention;

FIG. 3 is a timing chart of the reading process of the pixel unit according to one embodiment of the present invention;

FIG. 4 is a flow diagram of an imaging method according to an embodiment of the present invention; and

FIG. 5 is a schematic diagram of a system according to one embodiment the present invention.

### DETAILED DESCRIPTION OF THE PREFERRED EMBODIMENT

In order to make the purposes, the technical solution and advantages of the embodiment of the present invention clearer, the technical solutions in the embodiments of the present invention are clearly and completely described in the following with reference to the accompanying drawings in the embodiments of the present invention. Apparently, the described embodiments are only a part, but not all, of the embodiments of the invention. All other embodiments obtained by those of ordinary skill in the art based on the embodiments of the present invention without creative efforts are within the scope of the present invention.

In the following detailed description, reference can be made to each of the drawings which are a part of the present application and are for explaining particular embodiments of the present application. In the drawings, like reference numbers in different drawings describe substantially similar components. Each particular embodiment of the present application is described below with sufficient details, so that those of ordinary skill having knowledges and techniques relevant to the art can practice the technical solutions of the present application. It should be understood that it is also possible to use other embodiments to modify the structural, logical or electrical properties of the embodiments of the present application.

To address the problems in the prior art as described in the Background Section and according to one aspect of the present invention, there is proposed a pixel unit comprising a first photodiode, a first transfer transistor, which is coupled to a floating diffusion and transfers the charges generated by the first photodiode in response to incident light during an exposure period and accumulated in the photodiode during said exposure period to the floating diffusion; a second photodiode, a second transfer transistor, which is coupled to a floating diffusion and transfers the charges generated by the second photodiode in response to incident light during an exposure period and accumulated in the photodiode during said exposure period to the floating diffusion, wherein the photosensitive area of the second photodiode is different from the photosensitive area of the first photodiode; a capacitor, the first end of which is coupled to a specified voltage; a gain control transistor coupled between the second end of the capacitor and the floating diffusion for imposing an isolation control between the capacitor and the floating diffusion; a reset transistor coupled to the second end of the capacitor and the gain control transistor for resetting the level of the coupling point between the second end of the capacitor and the gain control transistor via a reset control signal; and a source-follower transistor coupled to the floating diffusion for amplifying and outputting the pixel signals.

In various exemplary embodiments, the pixel unit as described above further comprises a row select transistor, which is coupled to the output end of the source follower transistor and conduct a row output control on the pixel unit based on a row select control signal. In the pixel unit as described above, the gain control transistor changes the capacitance of the floating diffusion by controlling whether the capacitors are coupled to the floating diffusion. In the pixel unit as described above, the specified voltage coupled to the first end of the capacitor is a fixed voltage or a variable voltage. In the pixel unit as described above, the capacitor is a device capacitor or a parasitic capacitor to ground created at the connection point between the reset transistor and the gain control transistor.

To address the problems in the prior art as described in the Background Section and according to another aspect of the present invention, there is proposed an imaging apparatus, comprising: a pixel unit array comprising a plurality of pixel units arranged in rows and columns, wherein, each of the pixel unit comprises a first photodiode, a first transfer transistor, which is coupled to a floating diffusion and transfers the charges generated by the first photodiode in response to incident light during an exposure period and accumulated in the photodiode during said exposure period to the floating diffusion; a second photodiode, a second transfer transistor, which is coupled to a floating diffusion and transfers the charges generated by the second photodiode in response to incident light during an exposure period and accumulated in the photodiode during said exposure period to the floating diffusion, wherein the photosensitive area of the second photodiode is different from the photosensitive area of the first photodiode; a capacitor, the first end of which is coupled to a specified voltage; a gain control transistor coupled between the second end of the capacitor and the floating diffusion for imposing an isolation control between the capacitor and the floating diffusion; a reset transistor coupled to the second end of the capacitor and the gain control transistor for resetting the level of the coupling point between the second end of the capacitor and the gain control transistor via a reset control signal; and a source-follower transistor coupled to the floating diffusion for amplifying and outputting the pixel signals, and a peripheral circuit, for controlling the pixel array, and receiving and processing the image signals output by the pixel array.

In various exemplary embodiments of the imaging apparatus as described above, the gain control transistor changes the capacitance of the floating diffusion by controlling whether the capacitors are coupled to the floating diffusion. The imaging apparatus as described above further comprises a row select transistor, which is coupled to the output end of the source follower transistor and conduct a row output control on the pixel unit based on a row select control signal. In the imaging apparatus as described above, the specified voltage coupled to the first end of the capacitor is a fixed voltage or a variable voltage. In the imaging apparatus as described above, the capacitor is a device capacitor or a parasitic capacitor to ground created at the connection point between the reset transistor and the gain control transistor. In the imaging apparatus as described above, characterized in that, the capacitor is a device capacitor or a parasitic capacitor to ground created at the connection point between the reset transistor and the gain control transistor.

To address the problems in the prior art as described in the Background Section and according to another aspect of the present invention, there is proposed an imaging method in the pixel unit as described above, comprising: obtaining a first reset voltage of the floating diffusion in a first conversion gain mode; obtaining a second reset voltage of the floating diffusion in a second conversion gain mode; obtaining a second signal voltage of the floating diffusion in the second conversion gain mode; obtaining a first signal voltage of the floating diffusion in the first conversion gain mode; and obtaining a first valid signal through a dual-correlation operation based on the first reset voltage and the first signal voltage; obtaining a second valid signal through a dual-correlation operation based on the second reset voltage and the second signal voltage.

In various exemplary embodiments of the method as described above, wherein the first signal voltage and the second signal voltage come from the same photodiode.

According to the disclosures of the present invention, the gain control transistor effectively isolates the capacitor and the floating diffusion. A greater ratio of high conversion gain/low conversion can be achieved increasing the capacitance value, and a greater dynamic range is obtained by placing photodiodes having different photosensitive areas. The technical solution of the present invention allows a relatively small parasitic capacitance of the floating diffusion, a relatively larger high conversion gain, and an effectively improved noise performance of the circuit.

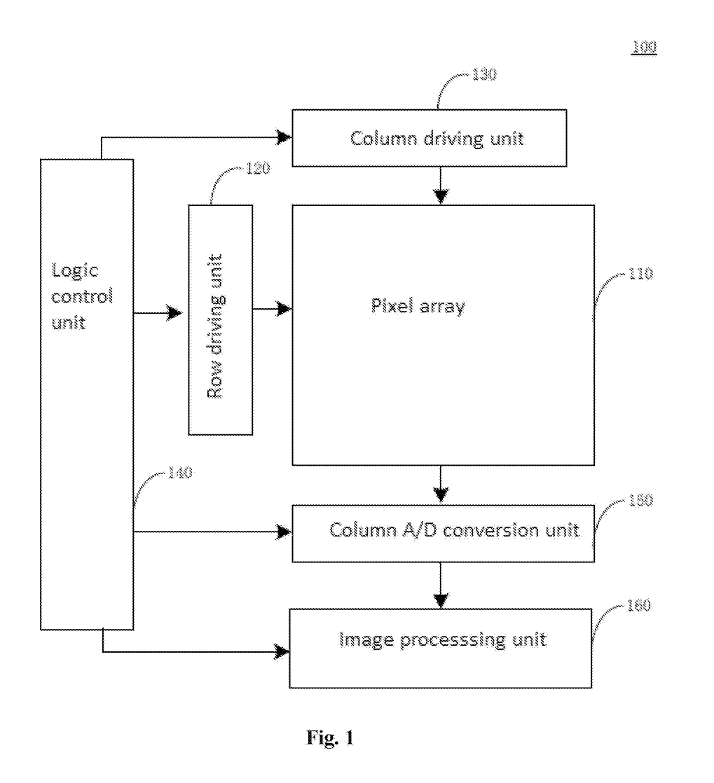

The term “pixel” in the invention refers to an electrical element containing a photosensitive device or other devices for transmitting electromagnetic signals to electrical signals. For the purposes of illustration, FIG. 1 shows a schematic diagram of the structure of a representative imaging apparatus comprising an array of pixels. The imaging apparatus 100 as shown in FIG. 1, for example a CMOS imaging apparatus, comprises a pixel array 110. The pixel array 110 comprises a plurality of pixels arranged in rows and columns. Each column of pixels in the pixel array 110 is selectively turned on by column select lines, and each row of pixels is selectively output by row select lines respectively. Logic control unit 140 performs logical control on each functional unit. Row driving unit 120 and column driving unit 130 control the pixel rows and columns. The pixels read are connected to a column A/D conversion unit 150.

The pixel information output from the column A/D conversion unit 150 is transferred to an image processing unit 160 for signal processing, and then outputting image information.

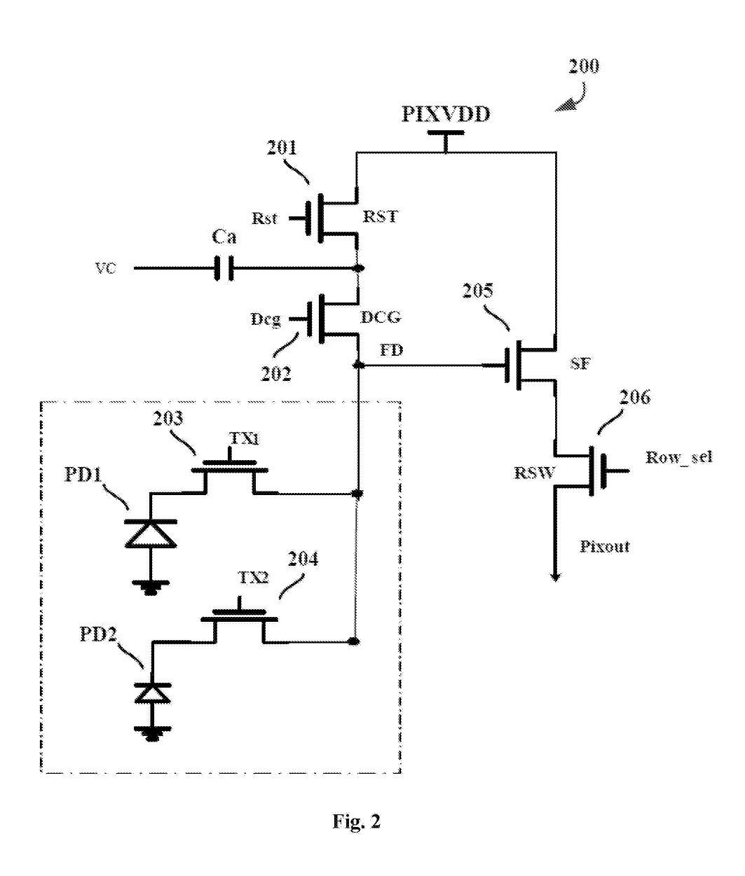

FIG. 2 is a schematic diagram of a pixel unit according to one embodiment of the present invention. Pixel 200 comprises a reset transistor 201, a gain control transistor 202, a capacitor Ca (or a parasitic capacitor, not limited to capacitance devices), a first transfer transistor 203, a first photodiode PD1, a second transfer transistor 204, a second photodiode PD2, a source follower transistor 205 and a row select transistor 206.

The first photodiode PD1 is connected to the source of the transfer transistor 203. The gate of the transfer transistor 203 may be coupled a signal TX1 control, so that the transfer transistor 203 may be responsive to signal TX1. When TX1 controls the transfer transistor to an “on” state, the charges in the first photodiode generated in response to incident light during an exposure period and accumulated in the photodiode during said exposure period are transferred to the floating diffusion FD. The second photodiode PD2 is connected to the source of the transfer transistor 204. The gate of the transfer transistor 204 may be coupled a signal TX2 control, so that the transfer transistor 204 may be responsive to signal TX2. When TX2 controls the transfer transistor to an “on” state, the charges in the second photodiode generated in response to incident light during an exposure period and accumulated in the photodiode during said exposure period are transferred to the floating diffusion FD. The gate of the source follower transistor 205 is connected to the floating diffusion FD, so that the output voltage of the source follower transistor 205 is substantially the same as the voltage of the floating diffusion FD 205 (i.e., the voltage at node A). The source of the source follower transistor 205 is directly or indirectly coupled to the output Pixout. The output end of the source follower transistor 205 is connected to the source of the row select transistor 206. The row select transistor 206 is coupled to an A/D conversion circuit via a row select control signal Row_sel. The gain control transistor 202 is coupled between the source of the reset transistor 201 and the transfer transistor 203, one end of the capacitor C is coupled between the reset transistor 201 and the gain control transistor 202, and the other end is coupled to a level VC. It can be understood that an embodiment of the level VC may be a certain fixed level (such as ground or other voltage) or a controllable varying level. The reset transistor 201 is controlled by a signal Rst to reset the floating diffusion FD.

According to one embodiment of the present invention, a first photodiode PD1 and a second photodiode PD2 have different photosensitive areas. That is, the same pixel is divided into two photosensitive regions having different areas to form two different photodiodes.

Further, based on the above structure, it is possible to adjust the capacitance C_{FD} of the floating diffusion FD and the conversion gain CG by controlling the switching of the gain control transistor 202.

When the signal DCG is at a high level, the gain control transistor 202 is at on state, so that the capacitor Ca is paralleled to the floating diffusion FD. With respect to the floating diffusion FD, the total capacitance C_{FD} thereof is the accumulation of the capacitor Ca and the original capacitance C_{FD} of the floating diffusion FD:

C_{FD}=Ca+C_{FD}

Thus, by increasing the capacitor Ca, the overall charge storage ability of the floating diffusion FD is improved, so that the pixels 200 have a higher full well capacity and thus the imaging apparatus has a wider light dynamic range.

According to one embodiment of the present invention, the first photodiode PD1's area is greater than the second photodiode PD2's area. That is, the first photodiode PD1 has a higher photosensitive capability than the second photodiode PD2 and thus transfer more charges. Correspondingly, when signal DCG is at a high level, the charges in the first photodiode PD1 or in the second photodiode are selected to be transferred to the floating diffusion FD.

When the signal DCG is at a low level, the gain control transistor 202 is at off state, so that the capacitor Ca is isolated from the floating diffusion FD. The total capacitance C_{FD} at the floating diffusion FD reduces to original capacitance C_{FD} of the floating diffusion FD. Correspondingly, when signal DCG is at a low level, the charges in the first photodiode PD1 or in the second photodiode are selected to be transferred to the floating diffusion FD. Conversion gain CG is calculated by the formula:

CG=q/C_{FD}=q/(C_{FD}+Ca)(uV/e) (1)

wherein q is the amount of charges in the floating diffusion, and uV/e represents the unit of the CG.

As can be seen from the above formula, the addition of the capacitor Ca decreases the conversion gain CG of the pixel 200. Correspondingly, the disconnection between the capacitor Ca and the floating diffusion FD increases the conversion gain. Thus, it is possible to control the pixel 200 to switch between high and low conversion gain modes by controlling the on-off of the gain control transistor 202. In addition, the ratio of the HCG/LCG can be obtained from the formula (1) as follows:

HCG/LCG=(C_{FD}+Ca)/C_{FD} (2)

It can be found from the above embodiment that the gain control transistor 202 of the present invention can efficiently improve the signal to noise ratio (SNR) of the pixels in the imaging apparatus and the light dynamic range. With the isolation between the capacitor Ca and the floating diffusion FD through the gain control transistor 202, it is possible to increase Ca to achieve a greater ratio of HCG/LCG, so as to have a larger dynamic range.

According to one embodiment of the present invention, it is possible to form a capacitor Ca by variety of ways. The capacitor Ca can be a device capacitor and a parasitic capacitor to ground created at the connection point between the reset transistor and the gain control transistor. According to another embodiment of the present invention, a device capacitor Ca is used, and the capacitor is connected to VC with a controllable voltage, i.e. in the manner as shown in FIG. 2.

Further, in the embodiment as shown in FIG. 2, there is no additional device at the FD point. Thus, the parasitic capacitor at the FD point is relatively small, i.e. the conversion gain (CG) at HCG (DCG tube is off) is relatively high. Thus, not only the noise performance is good, but also the ratio of HCG to LCG (DCG tube is on) at the same Cdcg condition is relatively high, thereby further increasing the dynamic range. In addition, there will be more flexibility on the selection of the connected potential of the other end of capacitor Ca in the circuit of FIG. 2. More importantly, the value of the capacitor Ca may not be limited by the driving ability of the control signal DCG. Because of the direct connection with the RST reset tube having a stronger driving ability (connecting power supply lines), and the isolation between the DCG tube and the FD point, the value of Ca can be larger, i.e. LCG can be smaller, thereby further relatively increasing the dynamic range.

Further, as an alternative embodiment of the present invention and, at the same time, as one of the important features of the present invention, the additional gain control transistor 202 and the capacitor Ca can have the same production steps with other transistors. Therefore, both the process cost and the process complexity will not be increased.

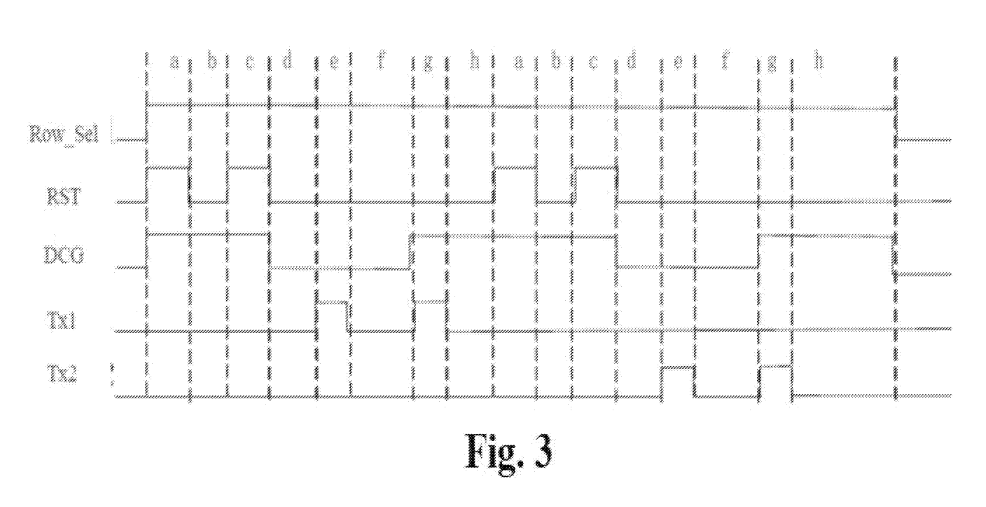

FIG. 3 is a reading process of a photodiode signal according to one embodiment of the present invention. First, the column stride signal ROW_SEL is set at a high level, enabling the reading process of the pixel 200.

Interval a: In this Interval, signal RST and signal DCG are set at high levels, the transistors 201 and 202 are conducted at this time. Thus, the potential at the floating diffusion will be reset to high level PIXVDD.

Interval b: In this Interval, the potential, VL01 at the floating diffusion in a low conversion gain mode is read. Since signal RST is at a low level, while signal DCG is held at a high level, and the reset transistor 201 is off and the gain control transistor 202 is on, therefore, the total capacitance on the floating diffusion FD C_{FD} comprises the original capacitance of the floating diffusion FD C_{FD} and the capacitor Ca, so that the conversion gain mode becomes small.

Interval c: In this Interval, signal RST is again at a high level, thus, both the reset transistor 201 and the gain control transistor 202 will be conducted, and the potential at node FD will be reset to high level PIXVDD.

Interval d: In this Interval, the potential VH01 at node FD in a high conversion gain mode is read. Since both signal RST and signal DCG are at low levels, the capacitor Ca cannot be electrically connected to the floating diffusion FD, therefore, the total capacitance C_{FD} on the floating diffusion FD will comprise the original capacitance C_{FD} of the floating diffusion FD only, so that the conversion gain becomes larger.

Interval e: In this Interval, signal TX1 is at a high level, thus the transfer transistor 203 is turned on, so that the charges in the first photodiode PD1 generated in response to incident light during an exposure period and accumulated in the photodiode during said exposure period are transferred to the floating diffusion FD. Since both signals RST and DCG are at low levels, therefore, it is at a high conversion gain mode at this time.

Interval f: In this Interval, signal TX1 is at a low level, and the potential VH10 of the FD in a high conversion gain mode is read.

Interval g: In this Interval, both signals DCG and TX1 are at high levels, thus, the charges in the photodiode PD1 generated in response to incident light during an exposure period and accumulated in the photodiode during said exposure period are transferred to the floating diffusion FD again. Obviously, the total capacitance C_{FD} on the floating diffusion FD comprises the original capacitance C_{FD} of the floating diffusion FD and the capacitor Ca.

Interval h: In this Interval, signal TX1 is at a low level, and the potential VL10 of the FD in a low conversion gain mode is read.

Through the above process, the reset voltages (VH01, VL01) of the floating diffusion FD and the signal voltages (VH10, VL10) transferred by the first photodiode FD1 at high and low conversion gain modes are obtained. Since the above signals are all sampled in the same signal output period, when the Interval between the two sampling times is less than the specified time threshold, the noise voltage of these two samples will be substantially the same. Since the sampling times are related, when the two sampling values are subtracted, the interference of the reset noise can be substantially eliminated, and the actual effective amplitude of the signal voltage in different conversion gain modes is obtained.

Through a similar process, the reset voltages (VH02, VL02) of the floating diffusion FD and the signal voltages (VH20, VL20) transferred by the second photodiode FD2 at high and low conversion gain modes are also obtained. Since the above signals are all sampled in the same signal output period, when the interval between the two sampling times is less than the specified time threshold, the noise voltage of these two samples will be substantially the same. Since the sampling times are also related, when the two sampling values are subtracted, the interference of the reset noise can be substantially eliminated, and the actual effective amplitude of the signal voltage in different conversion gain modes is obtained.

According to one embodiment of the present invention, the dark detailed image from the first photodiode PD1 is combined with the highlight image from the second photodiode PD2 by an algorithm to obtain an image with a higher dynamic range (HDR). Assuming the exposure time of the first photodiode PD1 as T1, and P10=VH10−VH01, P01=VL10−VL01; a first valid is P10+P01; the exposure time of the second photodiode PD2 as T2, and P20=VH20−VH02, P02=VL20−VL02; a second valid is P20+P02; the images from PD1 and PD2 can be combined by the following formula to obtain the image of an exposure time of T1 and T2:

P1=(P10+P01)+(P20+P02)T1/T2; and

P2=(P20+P02)+(P10+P01)T2/T1.

Further, an image with a high HDR is obtained by combining the two images having different exposure times. According to one embodiment of the present invention, the three features of the contrast, saturation and exposure characteristics of the multi-exposure image are combined into their corresponding weights image, and then the weight image is preprocessed according to the information entropy feature of the image; then the multi-exposure weight image is normalized to obtain information highlighting the respective regions; then the multi-exposure image and the normalized weight image are decomposed separately; finally, merging and reconstructing the images on each decomposed layer, a richer fused image is obtained.

According to another embodiment of the present invention, there is proposed a fusion method based on wavelet transform, comprising based on the edge detail characteristics, saturation characteristics and suitable exposure characteristics of the image, wavelet decomposition is performed on the multi-exposure image and the weight maps of its combined three characteristics, respectively, through specific wavelet transform fusion rules, the wavelet coefficients of each decomposed layer are fused and then inverse wavelet transform is performed, so that a fused image that can fully display most of the detailed information in the multi-exposure image sequence is obtained.

The algorithms in the above embodiment may require more computing power and consume more power, so may not be suitable for mobile devices with limited battery capacity. According to another embodiment of the present invention, the amount of calculation can be reduced by discarding supersaturated pixels. Specifically, it involves: determining whether P10+P01 is greater than a predetermined threshold; if P10+P01 is greater than the predetermined threshold, the P=(P20+P02)T1/T2; if P10+P01 is less than the first threshold, then P=(P10+P01)+(P20+P02)T1/T2; wherein the predetermined threshold is the product of the greatest exposure value with T2/T1. Those skilled in the art should understand that the above predetermined threshold is only an exemplification, and other manner could be used to determine the predetermined threshold.

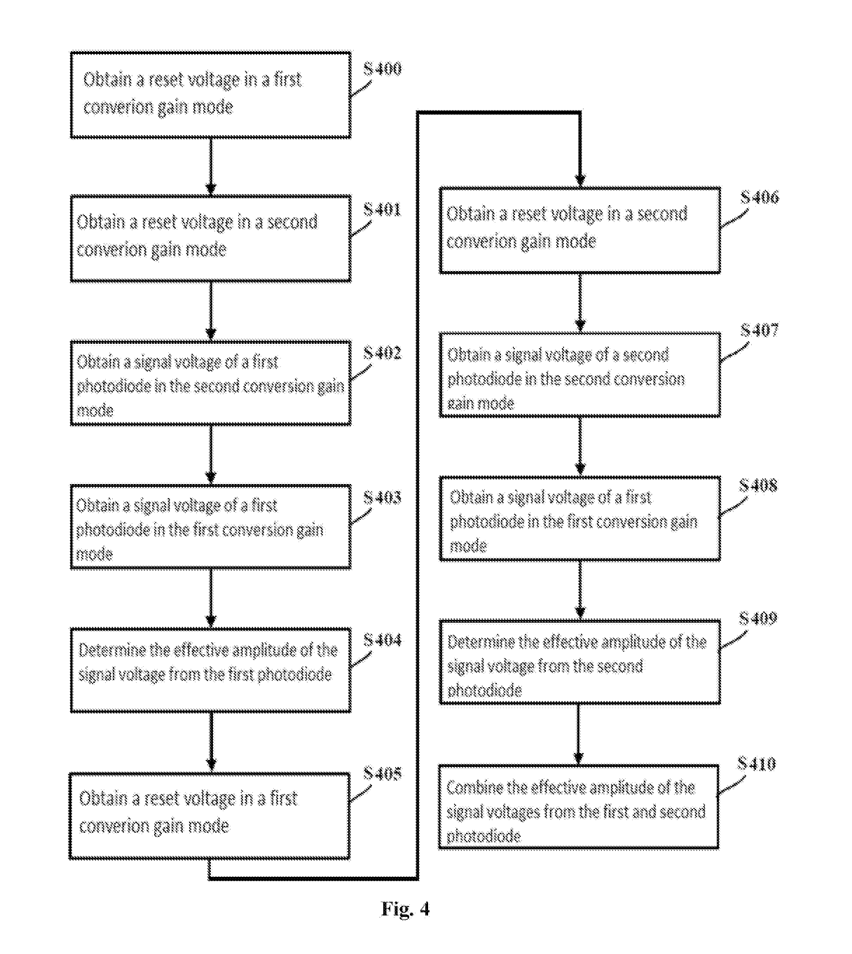

FIG. 4 is a flow chart of an imaging method according to the embodiment of the present invention.

In Step S400, the reset voltage of a first conversion gain mode is obtained. The gain control transistor is turned on so that the pixel circuit is in the first conversion gain mode, the first reset voltage of the floating diffusion FD is read.

In Step S401, the reset voltage of a second conversion gain mode is obtained. The gain control transistors are turned off, so that the pixel circuit is in the second conversion gain mode, and the second reset voltage of the floating diffusion is read.

In Step S402, the signal voltage of the first photodiode in the second conversion gain mode is obtained. The charges of the first photodiode generated in response to incident light during an exposure period and accumulated in the photodiode during said exposure period are transferred to the floating diffusion FD. It will be appreciated that the voltage at the floating diffusion FD at this time is determined by the electrons actually generated by the first photodiode, the noise at the floating diffusion FD, and the equivalent capacitance of the floating diffusion FD to the ground.

In Step S403, the signal voltage of the first photodiode in the first conversion gain mode is obtained. The gain control transistor is turned on, the voltage at the floating diffusion FD is determined by the electrons actually generated by the first photodiode, the noise at the floating diffusion FD, the equivalent capacitance of the floating diffusion FD to the ground and the capacitor Ca.

In Step S404, the effective amplitude of the signal voltage of the first photodiode is determined by a dual-correlation operation.

The reset voltages and signal voltages of the first photodiode at different conversion gain modes can be obtained through steps S400-S404. Based on the obtained reset voltages and signal voltages, signal voltage values actually generated by the first photodiode at different conversion gain modes can be determined through the dual-correlation operation, thus eliminating the influence of noise voltages.

In Step S405, the reset voltage of a first conversion gain mode is obtained. The gain control transistor is turned on so that the pixel circuit is in the first conversion gain mode, the first reset voltage of the floating diffusion FD is read.

In Step S406, the reset voltage of a second conversion gain mode is obtained. The gain control transistors are turned off, so that the pixel circuit is in the second conversion gain mode, and the second reset voltage of the floating diffusion is read.

In Step S407, the signal voltage of the second photodiode in the second conversion gain mode is obtained. The charges of the second photodiode generated in response to incident light during an exposure period and accumulated in the photodiode during said exposure period are transferred to the floating diffusion FD. It will be appreciated that the voltage at the floating diffusion FD at this time is determined by the electrons actually generated by the second photodiode, the noise at the floating diffusion FD, and the equivalent capacitance of the floating diffusion FD to the ground.

In Step S408, the signal voltage of the second photodiode in the first conversion gain mode is obtained. The gain control transistor is turned on, the voltage at the floating diffusion FD is determined by the electrons actually generated by the second photodiode, the noise at the floating diffusion FD, the equivalent capacitance of the floating diffusion FD to the ground and the capacitor Ca.

In Step S409, the effective amplitude of the signal voltage of the first photodiode is determined by a dual-correlation operation.

The reset voltages and signal voltages of the first photodiode at different conversion gain modes can be obtained through steps S405-S409. Based on the obtained reset voltages and signal voltages, signal voltage values actually generated by the second photodiode at different conversion gain modes can be determined through the dual-correlation operation, thus eliminating the influence of noise voltages.

In Step S410, the effective amplitudes of the signal voltages of the first and the second photodiode are combined. The dark detail image from the first photodiode PD1 is combined with the highlight image from the second photodiode PD2 by an algorithm to obtain an image with a higher dynamic range (HDR).

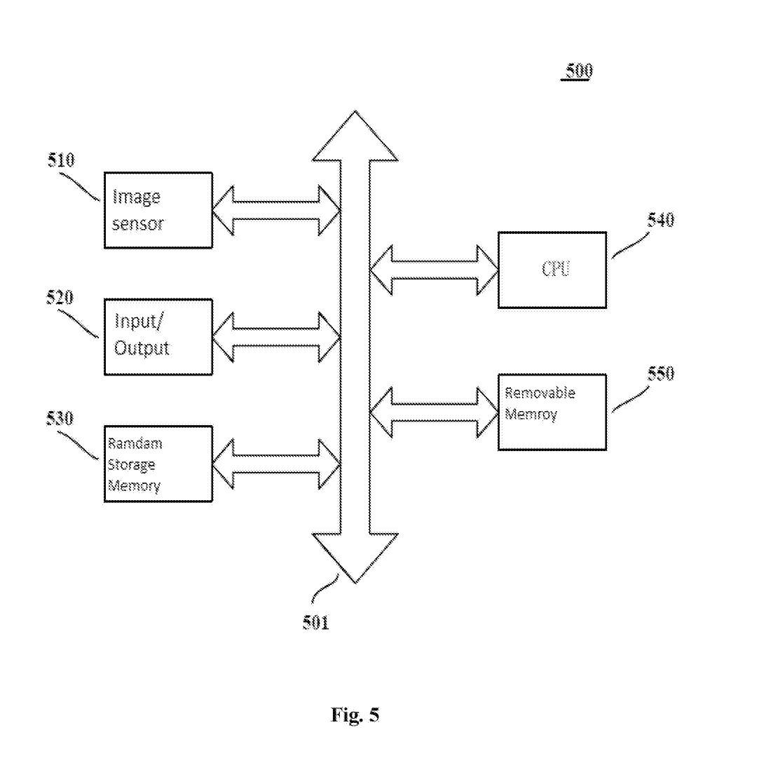

FIG. 5 is a schematic diagram of a system according to one embodiment the present invention. FIG. 5 illustrates a processing system 500 comprising an image sensor 510, wherein the image sensor 510 comprises the pixels as described in the present invention. The exemplified processing system 500 could comprise a digital circuit system of an image sensor device. Without any limitations, such a system could comprise a computer system, a camera system, a scanner, a machine vision, a vehicle navigator, a video phone, a surveillance system, an automatic focusing system, a star tracker system, a motion detection system, an image stabilization system and a data compression system.

The processing system 500 (e.g., a camera system) typically comprises a central processing unit (CPU) 540 (e.g. a microprocessor), which communicates with the input/output (I/O) device 520 via bus 501. Image sensor 510 also communicates with CPU 540 via bus 501. The processor based system 500 also comprises a random access memory (RAM) 530, and may comprise a removable memory 550 (e.g. a flash memory), which also communicates with the CPU 540 via the bus 501. The image sensor 510 may be combined with a processor (e.g. a CPU, a digital signal processor or a microprocessor), a single integrated circuit or a chip that is different from the processor may or may not have a memory storage device. The image combining and processing calculation can be performed by the image sensor 510 or the CPU 540.

Finally, it should be explained that, the above embodiments are only used for explaining the technical solution of present invention, and not for limitation thereto. Although the present invention has been explained in details with reference to the preferred embodiments, it should be understood by those skilled in the art that modifications and equivalent alternations can be made to the technical solution of present invention, and these modifications and equivalent alternations cannot depart the modified technical solution from the spirit and scope of the technical solution of present invention.

1. A pixel unit comprising:
a first photodiode,
a first transfer transistor, which is coupled to a floating diffusion and transfers the charges generated by the first photodiode in response to incident light during an exposure period and accumulated in the photodiode during said exposure period to the floating diffusion;
a second photodiode,
a second transfer transistor, which is coupled to a floating diffusion and transfers the charges generated by the second photodiode in response to incident light during an exposure period and accumulated in the photodiode during said exposure period to the floating diffusion, wherein the photosensitive area of the second photodiode is different from the photosensitive area of the first photodiode, and wherein said two transfer transistors share the same floating diffusion;
a capacitor, the first end of which is coupled to a specified voltage;
a gain control transistor coupled between the second end of the capacitor and the floating diffusion for imposing an isolation control between the capacitor and the floating diffusion;
a reset transistor coupled to the second end of the capacitor and the gain control transistor for resetting the level of the coupling point between the second end of the capacitor and the gain control transistor via a reset control signal; and
a source-follower transistor coupled to the floating diffusion for amplifying and outputting the pixel signals.

2. The pixel unit according to claim 1, further comprising a row select transistor, which is coupled to the output end of the source follower transistor, and conducts a row output control on the pixel unit based on a row select control signal.

3. The pixel unit according to claim 1, wherein the gain control transistor changes the capacitance of the floating diffusion by controlling whether the capacitors are coupled to the floating diffusion.

4. The pixel unit according to claim 1, wherein the specified voltage coupled to the first end of the capacitor is a fixed voltage or a variable voltage.

5. The pixel unit according to claim 1, wherein the capacitor is a device capacitor or a parasitic capacitor to ground created at the connection point between the reset transistor and the gain control transistor.

6. An imaging apparatus, comprising a plurality of pixel unit arrays arranged in rows and columns, wherein, each of the pixel unit comprises:
a first photodiode,
a first transfer transistor, which is coupled to a floating diffusion and transfers the charges generated by the first photodiode in response to incident light during an exposure period and accumulated in the photodiode during said exposure period to the floating diffusion;
a second photodiode,
a second transfer transistor, which is coupled to a floating diffusion and transfers the charges generated by the second photodiode in response to incident light during an exposure period and accumulated in the photodiode during said exposure period to the floating diffusion, wherein the photosensitive area of the second photodiode is different from the photosensitive area of the first photodiode, and wherein said two transfer transistors share the same floating diffusion;
a capacitor, the first end of which is coupled to a specified voltage;
a gain control transistor coupled between the second end of the capacitor and the floating diffusion for imposing an isolation control between the capacitor and the floating diffusion;
a reset transistor coupled to the second end of the capacitor and the gain control transistor for resetting the level of the coupling point between the second end of the capacitor and the gain control transistor via a reset control signal;
a source-follower transistor coupled to the floating diffusion for amplifying and outputting the pixel signals; and
a peripheral circuit for controlling the pixel array, and receiving and processing the image signals output by the pixel array output.

7. The imaging apparatus according to claim 6, wherein the gain control transistor changes the capacitance of the floating diffusion by controlling whether the capacitors are coupled to the floating diffusion.

8. The imaging apparatus according to claim 6, further comprising a row select transistor, coupled to the source follower transistor output end and conduct a row output control on the pixel unit based on a row select control signal.

9. The imaging apparatus according to claim 6, wherein the specified voltage coupled to the first end of the capacitor is a fixed voltage or a variable voltage.

10. The imaging apparatus according to claim 6, wherein the capacitor is a device capacitor or a parasitic capacitor to ground created at the connection point between the reset transistor and the gain control transistor.

11. An imaging method using the pixel unit according to claim 1, comprising:
obtaining a first reset voltage of the floating diffusion in a first conversion gain mode;
obtaining a second reset voltage of the floating diffusion in a second conversion gain mode;
obtaining a second signal voltage of the floating diffusion in the second conversion gain mode;
obtaining a first signal voltage of the floating diffusion in the first conversion gain mode;
obtaining a first valid signal through a dual-correlation operation based on the first reset voltage and the first signal voltage; and
obtaining a second valid signal through a dual-correlation operation based on the second reset voltage and the second signal voltage.
